(19) United States
(12) Patent Application Publication
(10) Pub. No.: US 2025/0158537 A1
(43) Pub. Date: May 15, 2025

(54) MODULAR MULTILEVEL POWER CONVERTER

(71) Applicant: Siemens Energy Global GmbH & Co. KG, München (DE)

(72) Inventors: Florian Frey, Spalt (DE); Christian Koch, Nürnberg (DE); Christian Schrammel, Schwarzenbruck (DE); Stephan Frenkel, Nürnberg (DE); Andreas Philipp, Winkelhaid (DE); Sebastian Semmler, Nürnberg (DE); Michael Zorawik, Hallerndorf (DE)

(21) Appl. No.: 18/835,115

(22) PCT Filed: Feb. 2, 2022
(86) PCT No.: PCT/EP2022/052415

§ 371 Date: Aug. 1, 2024

(51) Int. Cl. H02M 7/23; H02M 7/00

(52) U.S. Cl. CPC H02M 7/23; H02M 7/003

(57) ABSTRACT

A modular multilevel converter has at least one electrical series connection of modules. Each module has at least two electronic switching elements and an electrical energy store. In the multilevel converter, the modules are arranged in at least one support frame, which has frames defining a plurality of levels for receiving respectively at least one module. Accordingly, the frames of respective adjacent levels are electrically insulated from each other and the distance between these frames can be adjusted.

The invention relates to a modular multilevel converter having a plurality of modules. Such modular multilevel converters are used for example for converting one type of electrical current into another type of electrical current. Examples of this are the conversion of direct current to alternating current or vice versa. Modular multilevel converters can also be used for example for reactive power compensation.

The modular multilevel converter has at least one electrical series circuit of modules, wherein each module has at least two electronic switching elements and an electrical energy storage unit. The modules are arranged in at least one support structure. The support structure has frames that are arranged in multiple levels and set up for receiving in each case at least one module. The frames of respective adjacent levels are electrically insulated from one another. There must be minimum clearances between the frames of adjacent levels in order to prevent flashovers. The length of the minimum clearances is in this case dependent on the level of the voltages arising in the multilevel converter, in particular on the level of the voltage differences between adjacent frames. It is therefore conceivable to arrange insulation means with different dimensions between the individual levels when developing multilevel converters depending on the voltages arising in each case in order to implement the respectively required minimum clearance using said different insulation means having the different dimensions. However, it is time-consuming and expensive to develop, test and manufacture insulation means having different dimensions of this kind.

The invention is based on the object of specifying a modular multilevel converter that can easily be adapted to different voltages.

This object is achieved according to the invention by a modular multilevel converter as claimed in the independent patent claim. Advantageous configurations of the multilevel converter are specified in the dependent patent claims.

The invention discloses a modular multilevel converter, which has at least one electrical series circuit of modules, wherein each module has at least two electronic switching elements and an electrical energy storage unit, in which the modules are arranged in at least one (shelf-like) support structure (shelf unit), which has a respective frame in multiple levels for receiving in each case at least one module. In this case, the frames of respective adjacent levels are electrically insulated from one another. The distance between the frames of respectively adjacent levels can be adjusted (can be changed). The distance between said frames corresponds in particular to the clearance between said frames and thus the clearance between the modules of the frame of one level and the modules of the frame of the adjacent level. In this case, it is advantageous that the clearance between the frames can be adjusted, that is to say changed, on account of the adjustability of the distance between the frames, without having to redesign the support frame for this purpose. Therefore, clearances required in each case can be implemented quickly, easily and in a cost-effective manner.

This results in a multilevel converter that can be adapted quickly and easily to different voltages.

The modular multilevel converter can be designed so that
the distance between the individual frames can be adjusted in multiple stages.

In other words, the distance can be adjusted in stages/can be adjusted in steps. This has the advantage that the distance and thus the length of the clearance can be adjusted easily and in a reproducible manner by selecting the number of stages. Imprecise adjustment of the distance, which could possibly occur in the case of adjustment without using stages, is thereby avoided.

The modular multilevel converter can also be designed so that
post insulators are arranged between the individual frames. The post insulators support the frames and electrically insulate the frames from one another.

The modular multilevel converter can be designed so that
each end of the post insulators is secured to one of the frames by means of a post insulator bracket. The post insulator bracket may also be referred to as a mount. This post insulator bracket is advantageously used to implement the adjustability of the distance and thus the adjustability of the length of the clearance.

The modular multilevel converter can be designed so that
the post insulator brackets each have a first surface and a second surface, wherein the first surface is secured to one end of one of the post insulators and the second surface is secured to one of the frames. The post insulator bracket is thus designed to secure the post insulator to a respective frame of the support structure. The post insulator is secured to two (adjacent) frames of the support structure by means of two post insulator brackets.

The modular multilevel converter can be designed so that
the frames each have multiple first cutouts that are spaced apart from one another and/or the second surface of the post insulator bracket has multiple second cutouts that are spaced apart from one another. The first cutouts and the second cutouts make it possible to secure the post insulator bracket to the frame (for example by means of screws, threaded bolts or the like). In particular one cutout in the frame and multiple second cutouts in the second surface of the post insulator bracket that are spaced apart from one another are also sufficient for this. As an alternative, in particular multiple first cutouts in the frame that are spaced apart from one another and one second cutout in the second surface of the post insulator bracket are also sufficient. The first cutouts and/or the second cutouts are part of an adjustment apparatus for adjusting the distance between the frames. The support structure thus has an adjustment apparatus for adjusting the distance between the frames and/or levels.

The modular multilevel converter can be designed so that
the first cutouts are arranged in alignment and/or the second cutouts are arranged in alignment.

The modular multilevel converter can also be designed so that
the first cutouts correspond to the second cutouts.

The modular multilevel converter can also be designed so that
the distance between two successive first cutouts corresponds in each case to the distance between two successive second cutouts.

The modular multilevel converter can also be designed so that
the first cutouts and/or the second cutouts are each in the form of a bore.

The modular multilevel converter can also be designed so that
the post insulator brackets are connected to the respective frame in a force-fitting manner (in particular by means of a screw, a threaded bolt or the like, which extends in each case through one of the first cutouts and through one of the second cutouts). This achieves in particular an easily releasable connection.

The modular multilevel converter is explained in more detail in the following text using exemplary embodiments. To this end,

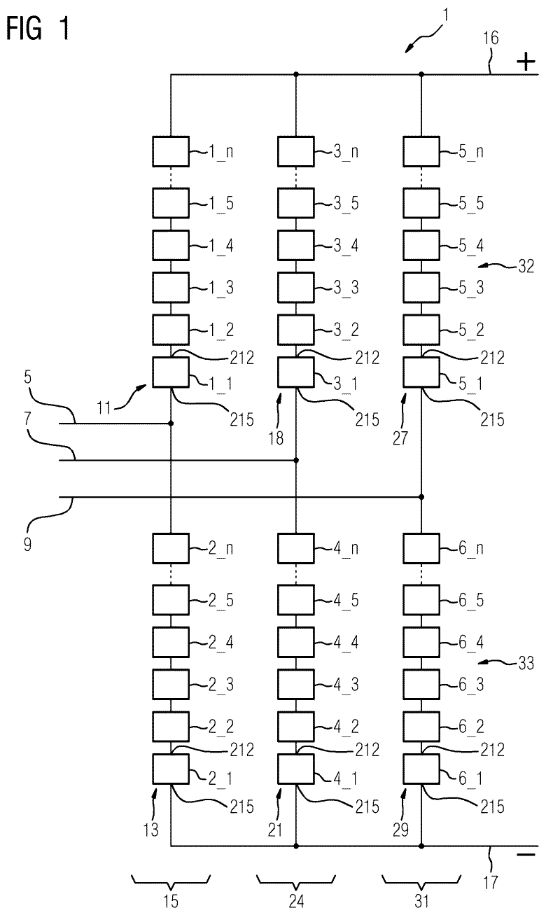

FIG. 1 shows an exemplary circuit diagram of a modular multilevel converter,

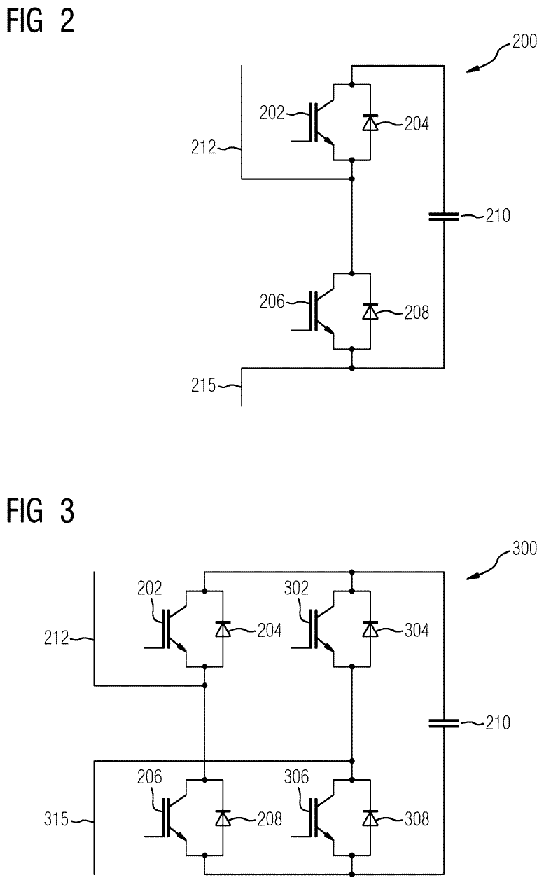

FIG. 2 shows an exemplary embodiment of a module of the modular multilevel converter,

FIG. 3 shows another exemplary embodiment of a module of the modular multilevel converter,

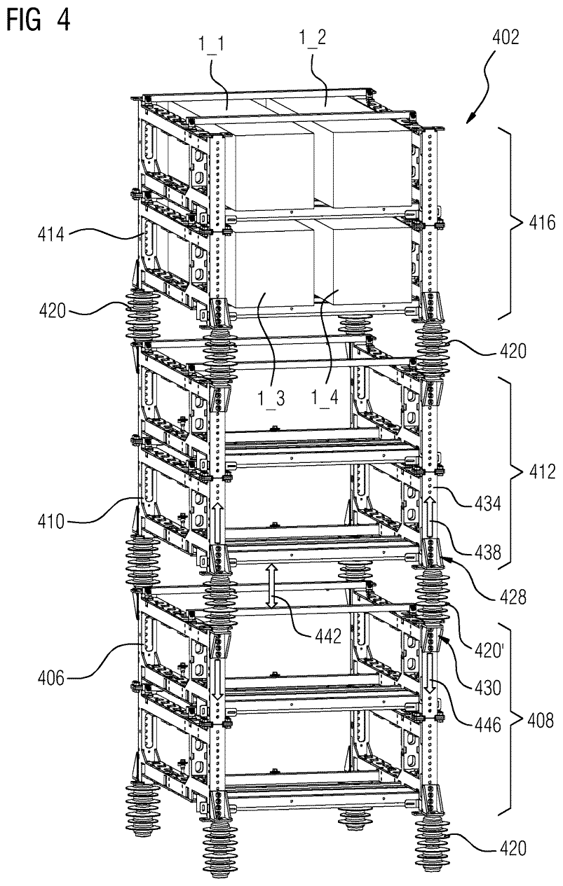

FIG. 4 shows an exemplary embodiment of a support structure for the modules of the multilevel converter,

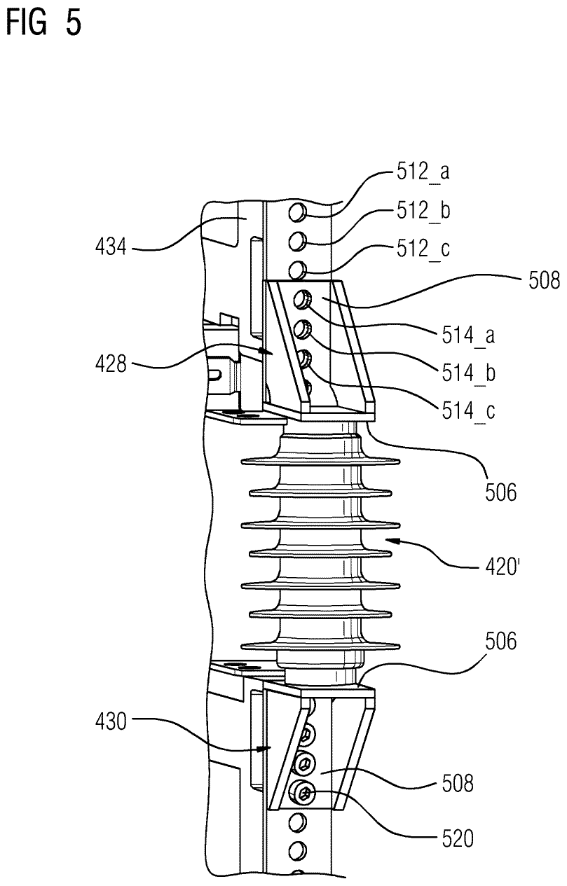

FIG. 5 shows an enlarged section from FIG. 4 with one post insulator and two post insulator brackets, and

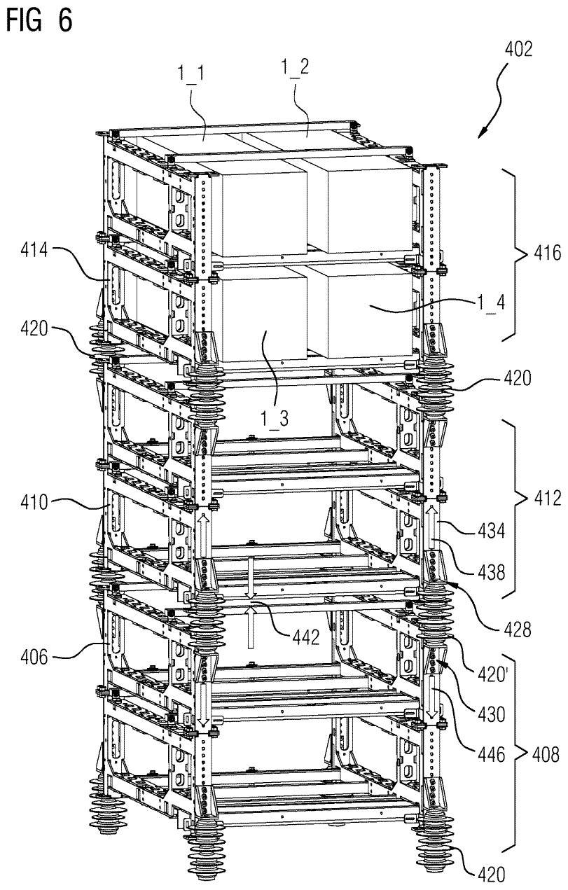

FIG. 6 shows the support structure with distances between the frames of respectively adjacent levels that are smaller compared to FIG. 4.

FIG. 1 shows an exemplary embodiment of a modular multilevel converter 1. This multilevel converter 1 has a first AC voltage terminal 5, a second AC voltage terminal 7 and a third AC voltage terminal 9. The first AC voltage terminal 5 is electrically connected to a first phase module branch 11 and a second phase module branch 13. The first phase module branch 11 and the second phase module branch 13 form a first phase module 15 of the converter 1. The end of the first phase module branch 11 furthest from the first AC voltage terminal 5 is electrically connected to a first DC voltage terminal 16; the end of the second phase module branch 13 furthest from the first AC voltage terminal 5 is electrically connected to a second DC voltage terminal 17. The first DC voltage terminal 16 is a positive DC voltage terminal; the second DC voltage terminal 17 is a negative DC voltage terminal.

The second AC voltage terminal 7 is electrically connected to one end of a third phase module branch 18 and to one end of a fourth phase module branch 21. The third phase module branch 18 and the fourth phase module branch 21 form a second phase module 24. The third AC voltage terminal 9 is electrically connected to one end of a fifth phase module branch 27 and to one end of a sixth phase module branch 29. The fifth phase module branch 27 and the sixth phase module branch 29 form a third phase module 31.

The end of the third phase module branch 18 furthest from the second AC voltage terminal 7 and the end of the fifth phase module branch 27 furthest from the third AC voltage terminal 9 are electrically connected to the first DC voltage terminal 16. The end of the fourth phase module branch 21 furthest from the second AC voltage terminal 7 and the end of the sixth phase module branch 29 furthest from the third AC voltage terminal 9 are electrically connected to the second DC voltage terminal 17. The first phase module branch 11, the third phase module branch 18 and the fifth phase module branch 27 form a positive-side converter portion 32; the second phase module branch 13, the fourth phase module branch 21 and the sixth phase module branch 29 form a negative-side converter portion 33.

Each phase module branch has a plurality of modules (1_1, 1_2, 1_3, 1_4 . . . 1_n; 2_1 . . . 2_n; etc.), which are electrically connected (by means of the module terminals thereof) in series (electrical series circuit). Such modules are also referred to as submodules. In the exemplary embodiment of FIG. 1, each phase module branch has n modules. The number of modules electrically connected in series by means of the module terminals thereof may be very different, at least three modules are connected in series; however, for example 50, 100 or more modules may also be electrically connected in series. In the exemplary embodiment, n=36: the first phase module branch 11 thus has 36 modules 1_1, 1_2, 1_3, . . . 1_36. The other phase module branches 13, 18, 21, 27 and 29 are of identical design.

A modular multilevel converter that has a bridge circuit is described by way of example in connection with FIG. 1. However, the modular multilevel converter may also be of a different design, for example it may have a delta circuit.

FIG. 2 shows an exemplary embodiment of a module 200 of the modular multilevel converter 1. The module may be for example one of the modules 1_1 . . . 6_n shown in FIG. 1.

The module 200 is designed as a half-bridge module 200. The module 200 has a first (disconnectable) electronic switching element 202 (first disconnectable semiconductor valve 202) having a first antiparallel-connected diode 204. The module 200 also has a second (disconnected) electronic switching element 206 (second disconnectable semiconductor valve 206) having a second antiparallel-connected diode 208 and an electrical energy storage unit 210 in the form of a capacitor 210. (The diode 204 or 208 connected in antiparallel with the electronic switching element may be present as an independent component; however, it may also already be present in the semiconductor structure of the electronic switching element in other exemplary embodiments. It may be the latter case for example for a reverse-conducting electronic switching element.) The first electronic switching element 202 and the second electronic switching element 206 are each designed as an IGBT (insulated-gate bipolar transistor). The first electronic switching element 202 is electrically connected in series with the second electronic switching element 206. A first galvanic module terminal 212 is arranged at the connecting point between the two electronic switching elements and 206. A second galvanic module terminal 215 is arranged at the terminal of the second electronic switching element 206, which is opposite the connecting point. The second module terminal 215 is also connected to a first terminal of the energy storage unit 210; a second terminal of the energy storage unit 210 is electrically connected to the terminal of the first electronic switching element 202, which is opposite the connecting point.

The energy storage unit 210 is thus electrically connected in parallel with the series circuit composed of the first electronic switching element 202 and the second electronic switching element 206. Appropriate actuation of the first electronic switching element 202 and the second electronic switching element 206 by way of a control device of the converter makes it possible to achieve a situation in which either the voltage of the energy storage unit 210 is output or no voltage is output (that is to say a zero voltage is output) between the first module terminal 212 and the second module terminal 215. Interaction of the modules of the individual phase module branches can thus generate the output voltage of the converter desired in each case.

FIG. 3 shows another exemplary embodiment of a module 300 of the modular multilevel converter. The module 300 may be for example one of the modules 1_1 . . . 6_n shown in FIG. 1. In addition to the first electronic switching element 202, second electronic switching element 206, first freewheeling diode 204, second freewheeling diode 208 and energy storage unit 210 already known from FIG. 2, the module 300 shown in FIG. 3 has a third electronic switching element 302 with a third antiparallel-connected freewheeling diode 304 and a fourth electronic switching element 306 with a fourth antiparallel-connected freewheeling diode 308. The third electronic switching element 302 and the fourth electric switching element 306 are each designed as an IGBT. In contrast to the circuit from FIG. 2, the second module terminal 315 is not electrically connected to the second electronic switching element 206 but instead to a center point (connecting point) of an electrical series circuit composed of the third electronic switching element 302 and the fourth electronic switching element 306.

The module 300 of FIG. 3 is what is known as a full-bridge module 300. This full-bridge module 300 is characterized in that, with appropriate actuation of the four electronic switching elements, either the positive voltage of the energy storage unit 210, the negative voltage of the energy storage unit 210 or a voltage with a value of zero (zero voltage) can selectively be output between the first module terminal 212 and the second module terminal 315. Therefore, the polarity of the output voltage can thus be reversed by means of the full-bridge module 300. In general, the multilevel converter 1 may have either only half-bridge modules 200, only full-bridge modules 300 or else half-bridge modules 200 and full-bridge modules 300.

FIG. 4 shows an example of a support structure 402 for modules of the modular multilevel converter 1. The shelf-like support structure 402 has a first frame 406, which is arranged in a first level 408 (first tier 408) of the support structure 402. In particular, the first frame 406 forms the first level 408 of the support structure 402. The first frame 406 in the first shelf level 408 forms a first shelf compartment 406 of the shelf unit 402. The support structure 402 also has a second frame 410, which is arranged in a second level 412 (second tier 412) of the support structure and forms the second level 412 of the support structure 402. The support structure 402 furthermore has an identical third frame 414, which is arranged in a third level 416 of the support structure or forms the third level 416 of the support structure 402. The frames are electrically insulated from one another by means of post insulators 420, wherein the post insulators 420 support the frames arranged above them in each case. The post insulators 420 of the support structure have an identical design and in particular all have the same length. The frames of respectively adjacent levels are thus electrically insulated from one another by means of the post insulators 420. For example, the third frame 414 of the third level 416 is thus electrically insulated from the second frame 410 of the second level 412 by means of the corresponding post insulators 420. For example, the second frame 410 of the second level 412 is also electrically insulated from the first frame 406 of the first level 408 by means of the corresponding post insulators 420. The first frame 406 of the first level 408 is furthermore electrically insulated by means of the corresponding post insulators 420 from the ground, not shown, on which the support structure 402 stands.

In the exemplary embodiment, the frames are each designed to receive four modules. It is shown by way of example that the third frame 414 receives a first module 1_1, a second module 1_2, a third module 1_3 and a fourth module 1_4. The modules 1_1 . . . 1_4 are in this case each symbolically shown as cuboids. In another exemplary embodiment, however, the third frame 414 may also be provided with only one module, with only 2 modules or with only 3 modules (or else with another number of modules). Each frame is thus designed to receive at least one module. The first frame 406 and the second frame 410 may receive modules in the same manner as the third frame 414.

Each post insulator 420 is connected to a frame by means of at least one post insulator bracket 428. For example, the post insulator 420′ arranged between the first frame 406 and the second frame 410 is connected to the second frame 410 by means of the post insulator bracket 428 and to the first frame 406 by means of another post insulator bracket 430. More specifically, in this case the post insulator 420′ is connected to a strut 434 of the second frame 410 by means of the post insulator bracket 428. In the exemplary embodiment, the strut 434 is aligned vertically. The post insulator bracket 428 can be connected to the strut 434 at various points; this is symbolized by the arrow 438. This arrow represents a direction 438 in which the post insulator bracket 428 can be secured to the frame in an offset manner, proceeding from the position shown in FIG. 4. Further details relating to the post insulator bracket are shown in FIG. 5.

A distance 442 between the first frame 406 and the second frame 410 is marked in FIG. 4 for example by means of an arrow. This distance 442 corresponds to the clearance between the first frame 406 and the second frame 410. If the post insulator bracket 428 is offset in the direction of the arrow 438 and secured to another point of the strut 434 (that is to say to another point of the frame 410), the distance 442 and thus the clearance becomes smaller. The same applies to the other post insulator bracket 430: if the other post insulator bracket 430 is offset in the direction of the arrow 446 and is secured/mounted to another point of the first frame (to the corresponding strut), the distance 442 then also become smaller. The distance 442/the clearance 442 between the frames can thus be adjusted by means of the post insulator bracket(s). If respective modules of another electrical phase of the converter are arranged in each level/in each frame, the distance 442 then represents the distance between various phases of the converter.

The post insulator brackets that connect the first frame 406 to the post insulators 420 that support said first frame 406 can be used to adjust the distance between the first frame 406 and the ground on which the support structure 402 stands.

FIG. 5 shows an enlarged illustration of a section from FIG. 4 with the post insulator 420′. The post insulator 420′ is secured to the strut 434 of the second frame 410 by means of the post insulator bracket 428. In the exemplary embodiment, the post insulator bracket 428 is designed as a bracket element. In other exemplary embodiments, the post insulator brackets may also be of a different design.

The post insulator bracket 428 has a first surface 506 and a second surface 508. In the exemplary embodiment, the first surface 506 and the second surface 508 are at a right angle to one another. One end of the post insulator 420′ is secured to the first surface 506. The second surface 508 is secured to the frame 410, more specifically to the strut 434 of the frame 410. In FIG. 5, the second surface 508 is covered, which is why the reference line of the reference sign 508 cannot point exactly to the second surface. The second surface 508 is that surface of the post insulator bracket 428 that is in contact with the strut 434 of the second frame 410 (contact surface of the post insulator bracket 428 with the strut 434 of the second frame 410). The second surface 508 is thus the surface of the post insulator bracket 428 that faces the strut 434 of the second frame of 410. Another example of the second surface 508 is the surface of the other post insulator bracket 430 that is in contact with the strut of the first frame 406.

The frame 410 (in this case: the strut 434) has first cutouts 512_a, 512_b, 512_c, etc. that are spaced apart from one another, with these first cutouts being in the form of bores in the exemplary embodiment. The second surface 508 has second cutouts 514_a, 514_b, 514_c, etc. that are spaced apart from one another, with these second cutouts also being in the form of bores in the exemplary embodiment.

The first cutouts 512 are arranged in alignment; the second cutouts 514 are also arranged in alignment. The first cutouts 512 correspond to the second cutouts 514. In particular, the distance between two successive first cutouts 512 is as large as the distance between two successive second cutouts 514. Due to these identical distances between the successive first cutouts, the distance between the individual frames can be adjusted in several stages (staged adjustment, stepped adjustment of the distance).

A screw extends through one of the first cutouts 512 and through the corresponding second cutout 514, which connects the post insulator bracket 428 to the frame 410 in a force-fitting manner. In the exemplary embodiment, the post insulator bracket 428 is connected to the strut 434 and thus to the second frame 410 by means of 4 screws. For better perceptibility, these screws 520 are shown only for the further post insulator bracket 430, which means that the second cutouts 514 can be identified for the post insulator bracket 428.

FIG. 6 shows the support structure 402 of FIG. 4 in the event that the post insulator brackets are secured to a different point of the respective frame. In this case, for example, the post insulator brackets 428 and 430 are secured to a securing point on the respective frame that is offset in the direction of the arrow 438 and in the direction of the arrow 446, respectively, in comparison with the securing point shown in FIG. 4. As a result, the distance 442 becomes smaller; the distance between the second frame 410 and the third frame 414 also become smaller. This corresponds to a decreasing clearance 442 between the frames. The distance between the individual frames or levels of the support structure can thus be adjusted in multiple stages (in stages, in steps). This distance can be adjusted by means of an adjustment apparatus, which has the first cutouts and the second cutouts. The adjustment apparatus is thus designed to adjust the distance between the individual frames in multiple stages.

A smaller clearance/a smaller distance 442 of this kind is sufficient for example for a multilevel converter having a comparatively small voltage difference between the individual modules (compared to FIG. 4). Due to the reduced distance 442, the support structure 402 may be made more compact, which results in space/installation space being saved. This also results in a reduction in costs.

The support structure 402 described is to be understood purely by way of example. In other exemplary embodiments, the support structure may be of a different design. In particular, the support structure may have a different number of frames or levels or a different number of modules may be arranged in each frame.

The invention has disclosed a modular multilevel converter in which in particular the distances between the levels or phases, the distance from the ground and/or the distance from the top can be changed (scaled) according to the respective voltage range required. The creepage paths remain constant here, as long as identical post insulators are used. The same post insulators can therefore be used for many different voltages until the greatest possible clearance is achieved with these post insulators. The adjustable distances, in particular the phase distances, are formed during assembly by means of (in particular vertically) displaceable post insulated brackets. It is therefore possible to realize a converter with minimal clearances that are tailored to the respective application.

As a result, the variation of the clearance distances is not associated with a reselection or redesign of post insulators with subsequent testing etc. As the multiplicity of variants of converters increases, the engineering effort and document management effort is therefore advantageously not increased. In addition, the proportion of carryover parts (in this case: identical post insulators) for various converters increases, which has a positive effect on the retail costs.

As a consequence thereof, for example, stress analyses for variant-specific post insulators are also no longer necessary. The adaptation effort is lower even for temporary changes in the specification of the converter.

The invention has described a modular multilevel converter that can easily be adapted to different voltages. As a result, it is possible to easily implement the required minimum clearances so that an unnecessarily large installation space due to overdimensioned clearances is avoided.

### REFERENCE SIGNS

1 Multilevel converter
5 First AC voltage terminal
7 Second AC voltage terminal
9 Third AC voltage terminal
11 First phase module branch
13 Second phase module branch
15 First phase module
16 First DC voltage terminal
17 Second DC voltage terminal
18 Third phase module branch
21 Fourth phase module branch
24 Second phase module
27 Fifth phase module branch
29 Sixth phase module branch
31 Third phase module
32 Positive-side converter portion
33 Negative-side converter portion
1_1 . . . 6_n Modules
200 Module
202 First electronic switching element
204 First antiparallel-connected diode
206 Second electronic switching element
208 Second antiparallel-connected diode
210 Electrical energy storage unit
212 First module terminal
215 Second module terminal
302 Third electronic switching element
304 Third antiparallel-connected diode
306 Fourth electronic switching element
308 Fourth antiparallel-connected diode
315 Second module terminal
402 Support structure
406 First frame
408 First level
410 Second frame
412 Second level
414 Third frame
416 Third level
420 Post insulator
420′ Post insulator
428 Post insulator bracket
430 Post insulator bracket
434 Strut
438 Direction
442 Distance
446 Direction
506 First surface
508 Second surface
512 First cutouts
514 Second cutouts
520 Screw

1.-11. (canceled)

12. A modular multilevel converter, comprising:
at least one electrical series circuit of modules, each of said modules having at least two electronic switching elements and an electrical energy storage unit; and
at least one support structure in which said modules are disposed, said at least one support structure having frames each defining one of a plurality of levels for receiving in each case at least one of said modules, wherein said frames of respective adjacent said levels are electrically insulated from one another and wherein a distance between said frames is adjustable.

13. The modular multilevel converter according to claim 12, wherein the distance between individual ones of said frame is adjusted in multiple stages.

14. The modular multilevel converter according to claim 12, further comprising post insulators disposed between individual ones of said frames.

15. The modular multilevel converter according to claim 14, further comprising post insulator brackets, each end of said post insulators is secured to one of said frames by means of one of said post insulator brackets.

16. The modular multilevel converter according to claim 15, wherein said post insulator brackets each have a first surface and a second surface, wherein said first surface is secured to one end of one of said post insulators and said second surface is secured to one of said frames.

17. The modular multilevel converter according to claim 16, wherein:
said frames each have a plurality of first cutouts formed therein and said first cutouts are spaced apart from one another; and/or
said second surface of said post insulator bracket has a plurality of second cutouts formed therein and said second cutouts are spaced apart from one another.

18. The modular multilevel converter according to claim 17, wherein said first cutouts are disposed in alignment and/or said second cutouts are disposed in alignment.

19. The modular multilevel converter according to claim 17, wherein said first cutouts correspond to said second cutouts.

20. The modular multilevel converter according to claim 17, wherein a first distance between two successive said first cutouts corresponds in each case to a second distance between two successive said second cutouts.

21. The modular multilevel converter according to claim 17, wherein said first cutouts and/or said second cutouts are each in a form of a bore.

22. The modular multilevel converter according to claim 15, wherein said post insulator brackets are connected to a respective one of said frames in a force-fitting manner.
